(19) United States
(12) Patent Application Publication
(10) Pub. No.: US 2020/0267846 A1
(43) Pub. Date: Aug. 20, 2020

(54) FEEDTHROUGH FABRICATION METHOD AND METHOD OF FABRICATING ENCAPSULATED ELECTRONIC DEVICE USING FEEDTHROUGH FABRICATED BY THE FEEDTHROUGH FABRICATION METHOD

(71) Applicant: TODOC CO., LTD., Seoul (KR)

(72) Inventors: Kyou-Sik MIN, Suwon-si (KR); Jin Won KIM, Seoul (KR)

(21) Appl. No.: 16/279,578

(22) Filed: Feb. 19, 2019

(51) Int. Cl. H05K 3/40; H05K 3/00; H05K 3/28; H05K 3/30; H05K 5/02

(52) U.S. Cl. CPC H05K 3/4046; H05K 3/0026; H05K 3/0052; H05K 2203/065; H05K 3/303; H05K 5/0247; H05K 2203/107; H05K 3/28

(57) ABSTRACT

A feedthrough fabrication method and a method of fabricating an encapsulated electronic device using a feedthrough fabricated by the feedthrough fabrication method. A high-strength feedthrough can be conveniently fabricated, and the position and shape of the feedthrough is freely modifiable. A feedthrough sheet, an insulating sheet, and a package sheet are stacked sequentially in a vertically downward direction. The feedthrough sheet, the insulating sheet, and the package sheet are diffusion-bonded. Holes are formed to penetrate through the package sheet and the insulating sheet. A plurality of feedthrough electrodes are formed by processing the feedthrough sheet, such that the feedthrough electrodes close the holes, respectively, and are spaced apart from each other.

### BACKGROUND OF THE INVENTION

### Field of the Invention

The present disclosure relates generally to a method of fabricating a feedthrough and, more particularly, to a method of fabricating a feedthrough used in an encapsulated electronic device, such as a bio-implantable electronic device, and a method of fabricating an encapsulated electronic device using a feedthrough fabricated by the feedthrough fabrication method.

### Description of the Related Art

The information described or disclosed in the Background of the Invention section should not be taken as an acknowledgment or as any form of suggestion that this information forms a prior art of the Claims appended herein.

A bio-implantable electronic device encapsulates a circuit, including a microchip and the like. When implanted into a body, the bio-implantable electronic device protects the circuit from body fluids, ions, and the like. The term “encapsulated electronic device” used herein as a comprehensive term including the bio-implantable electronic device includes a package encapsulating the circuit and a feedthrough electrically connected to the circuit and bonded to the package to seal the package. The circuit can be electrically connected to the outside of the package via the feedthrough. The feedthrough of an encapsulated electronic device of the related art includes an annular coupling portion coupled to an opening of the package, an insulating portion surrounded by the coupling portion, and a conductive portion comprised of metal pins fitted into a plurality of through-holes in the insulating portion such that both ends of the metal pins are exposed. In general, the package and the coupling portion are coupled and sealed by laser welding, and the insulating portion and the coupling portion or the insulating portion and the metal pins of the conductive portion are coupled and sealed by brazing or diffusion bonding. However, the feedthrough and a method of fabricating the same experience the following problems.

A process of inserting the metal pins into the plurality of through-holes in the insulating portion in a corresponding manner is necessary. To automate this process, robot equipment having a 5-axis degree of freedom must be introduced, thereby incurring excessive cost. When this process is manually performed to reduce cost, productivity may be reduced, which is problematic.

Brazing is a process of applying liquid filler to or inserting solid filler into boundaries of two objects, followed by heating to a melting point of the filler and then cooling. When the insulating portion and the metal pins are brazed, adjacent filler portions may be melted to contact each other, thereby causing short circuit in the metal pins, which is problematic.

When diffusion bonding is performed instead of brazing, pressure is concentrated to boundaries between two objects in a high-temperature and/or high-vacuum environment. When the boundaries are limited, the objects may be fractured at a high pressure.

In a process of forming an insulating portion having through-holes, the positions of metal pins are determined corresponding to the through-holes, which form feedthrough channels through which the metal pins are connected to a circuit. Once the insulating portion having the through-holes is formed, it is impossible to change the positions of the feedthrough channels, which is problematic.

Korean Patent No. 10-0619103 discloses an implant for an artificial cochlea and a method of manufacturing the same, and Korean Patent No. Korean Patent No. 10-0619105 discloses an implant for an artificial cochlea.

Although such related-art approaches disclose solutions for improving the encapsulation of feedthroughs, no techniques for improving the productivity of feedthroughs are disclosed.

### RELATED ART DOCUMENT

Patent Document 1: Korean Patent No. 10-0619103 (dated on Aug. 25, 2006)
Patent Document 2: Korean Patent No. 10-0619105 (dated on Aug. 25, 2006)

### SUMMARY OF THE INVENTION

Accordingly, the present invention has been made keeping in mind the above problems occurring in the related art, and the present invention proposes a feedthrough fabrication method suitable for mass production due to high productivity and low unit price, and a method of fabricating an encapsulated electronic device using a feedthrough fabricated by the feedthrough fabrication method.

The object of the present invention is not limited to the aforementioned description, and other objects not explicitly disclosed herein will be clearly understood by those skilled in the art to which the present invention pertains from the description provided hereinafter.

In order to achieve the above object, according to one embodiment of the present invention, a feedthrough fabrication method may include: stacking a feedthrough sheet, an insulating sheet, and a package sheet sequentially in a vertically downward direction, and diffusion-bonding the feedthrough sheet, the insulating sheet, and the package sheet; forming holes to penetrate through the package sheet and the insulating sheet; and forming a plurality of feedthrough electrodes by processing the feedthrough sheet, such that the plurality of feedthrough electrodes close the holes, respectively, and are spaced apart from each other.

In addition, the feedthrough fabrication method may further include cutting the insulating sheet and the package sheet in a shape required for an encapsulated electronic device.

Furthermore, in the cutting the insulating sheet and the package sheet, the insulating sheet and the package sheet may be cut by processing portions of the insulating sheet, located in peripheral portions of the shape required for the encapsulated electronic device, so that portions of the package sheet are exposed, and cutting the package sheet along the exposed portions thereof.

In addition, in the forming the holes, the holes may be formed by etching the package sheet and the insulating sheet such that a bottom surface of the feedthrough sheet is exposed downwardly.

Furthermore, the forming the plurality of feedthrough electrodes may include closing the holes with the feedthrough electrodes, respectively, and processing and removing portions of the feedthrough sheet using a laser or a computerized numerical control (CNC) machine to be separated from each other.

According to another embodiment of the present invention, provided is a method of fabricating an encapsulated electronic device using a feedthrough fabricated by a feedthrough fabrication method. The feedthrough fabrication method includes stacking a feedthrough sheet, an insulating sheet, and a package sheet sequentially in a vertically downward direction, and diffusion-bonding the feedthrough sheet, the insulating sheet, and the package sheet, forming holes to penetrate through the package sheet and the insulating sheet, and forming a plurality of feedthrough electrodes by processing the feedthrough sheet, such that the plurality of feedthrough electrodes close the holes, respectively, and are spaced apart from each other. The method of fabricating an encapsulated electronic device may include: connecting the feedthrough electrodes to a circuit; forming a package connected to a peripheral portion of the package sheet to enclose the circuit; and connecting the feedthrough electrodes to outer electrodes through the holes, the outer electrodes being exposed externally from the package and connected to the package sheet, and encapsulating the outer electrodes and the feedthrough electrodes.

Furthermore, the forming the package may include bonding the package to a cut side surface of the package sheet by laser welding while enclosing the circuit and the insulating sheet, the package being made of titanium.

In addition, the encapsulating the outer electrodes and the feedthrough electrodes may include: forming openings in the outer electrodes to be connected the holes; and connecting the feedthrough electrodes to the outer electrodes through the openings, respectively, by one selected from among wire bonding, welding, and soldering.

Furthermore, the encapsulating the outer electrodes and the feedthrough electrodes may include: encapsulating connecting portions of the outer electrodes and the feedthrough electrodes by applying a cover including epoxy to the connecting portions; enclosing the applied cover with a package cap; and welding the package cap to the package.

According to an embodiment as disclosed herein, it is possible to advantageously improve productivity and reduce fabrication costs by automating processes, so that mass production can be carried out, since no processes incur excessive cost for automation.

It is possible to change the position and shape of the feedthrough electrodes and the shape of the feedthrough in a simple manner. The feedthrough may advantageously be used as a neural electrode for a flat retina implant or the like, in addition to being used as a feedthrough.

Since no filler is used for bonding the insulating sheet and the feedthrough electrodes, there is advantageously no risk of short circuit between the feedthrough electrodes.

Since diffusion bonding is performed over wider boundary surfaces, advantages, such as no risk of fracture due to diffusion bonding and high mechanical strength, can be obtained.

Since the effects of the present invention are exerted by contents described herein, regardless of perception of the inventors, the above-described effects are merely specific examples of the effects obtainable from the present invention and should not be understood as all effects that the inventors have perceived or are obtainable from the present invention.

In addition, the effects of the present invention should be determined additionally on the basis of the complete description of the specification. Although not explicitly described, any effects that may be recognized by those skilled in the art to which the present invention relates, on the basis of the description of the specification, shall be regarded as the effects described herein.

### BRIEF DESCRIPTION OF THE DRAWINGS

The above and other objects, features and advantages of the present invention will be more clearly understood from the following detailed description when taken in conjunction with the accompanying drawings, in which:

FIG. 1 illustrates process diagrams of a feedthrough fabrication method according to an embodiment of the present disclosure;

FIG. 2 is a flowchart of the feedthrough fabrication method illustrated in FIG. 1;

FIG. 3 illustrates process diagrams of a method of fabricating an encapsulated electronic device according to an embodiment of the present disclosure; and

FIGS. 4 and 5 are process diagrams illustrating a method of fabricating an encapsulated electronic device according to another embodiment of the present disclosure.

### DETAILED DESCRIPTION OF THE INVENTION

Hereinafter, a feedthrough fabrication method and a method of fabricating an encapsulated electronic device using a feedthrough fabricated by the feedthrough fabrication method according to exemplary embodiments will be described, in relation to configurations, operations, and effects thereof, with reference to the drawings. For reference, in the drawings, components are omitted or schematically illustrated for the sake of convenience and clarity, and the size of each component may not reflect the actual size. Throughout this document, the same reference numerals and symbols will be used to designate the same or like components. In individual drawings, reference numerals of the same components will be omitted.

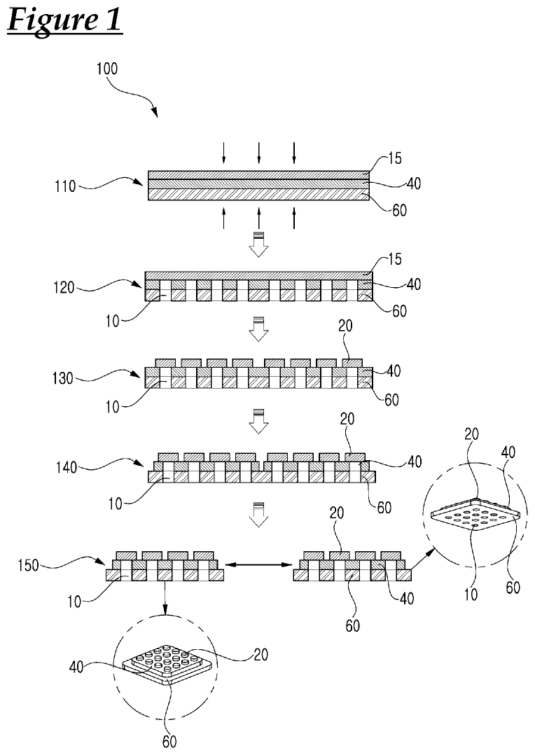

FIG. 1 illustrates process diagrams of a feedthrough fabrication method according to an embodiment of the present disclosure.

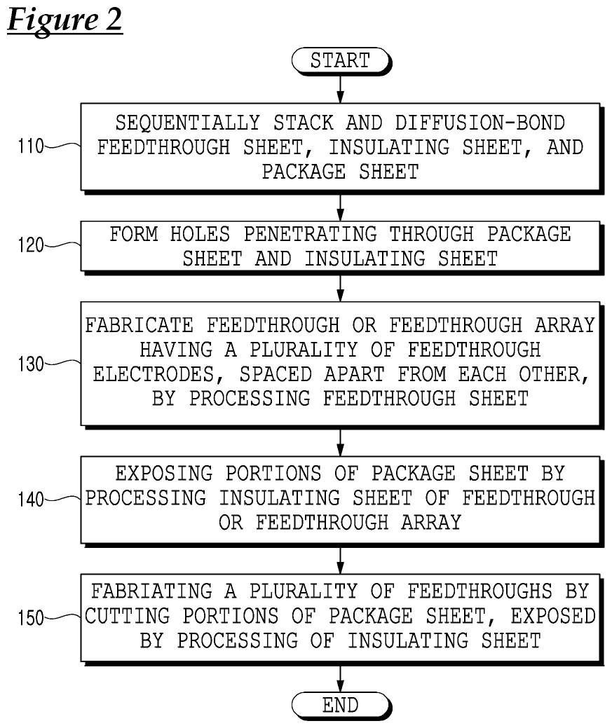

FIG. 2 is a flowchart of the feedthrough fabrication method illustrated in FIG. 1.

As illustrated in FIGS. 1 and 2, a feedthrough fabrication method 100 includes first to fifth steps 110, 120, 140, and 150.

In the first step 110, a feedthrough sheet 15, an insulating sheet 40, and a package sheet 60 are sequentially stacked in a vertically downward direction, and diffusion bonding is performed.

Specifically, in the first step 110, the feedthrough sheet 15 is implemented as a film or a sheet, the insulating sheet 40 having the same shape as the feedthrough sheet 15 is closely adjoined to the bottom surface of the feedthrough sheet 15, and the package sheet 60 having the same shape as the insulating sheet 40 is closely adjoined to the bottom surface of the adjoined to the bottom surface of the. The package sheet 60 is a sheet-shaped member made of the same material as a package, which is to be bonded to the package sheet 60 as will be described later.

The feedthrough sheet 15, the insulating sheet 40, and the package sheet 60 are bonded to each other by diffusion bonding using a press in a high-temperature and high-vacuum environment, and the feedthrough sheet 15 is implemented as a conductive material including a Pt—Ir alloy (first step 110).

The insulating sheet 40 may be made of one selected from among, but not limited to, zirconia, alumina, and glass, while the package sheet 60 may be made of a titanium alloy. Since the feedthrough sheet 15, the insulating sheet 40, and the package sheet 60, in the shape of a film or sheet, are diffusion-bonded, with the top and bottom surfaces being closely adjoined to each other, wide boundary surfaces can be produced, thereby advantageously preventing the sheets from being fractured or deformed in high-temperature and high-vacuum environments (first step 110).

In the second step 120, after the feedthrough sheet 15, the insulating sheet 40, and the package sheet 60 are closely adjoined to each other, holes 10 are formed to penetrate sequentially through the package sheet 60 and the insulating sheet 40 using one of etching and laser processing, so that the holes 10 are spaced apart from each other.

When the holes 10 penetrating through the package sheet 60 and the insulating sheet 40 are formed, portions of the bottom surface of the feedthrough sheet 15 are exposed downwardly through the holes 10, and the bottom surface portions of the feedthrough sheet 15 exposed through the holes 10, the cross-sectional surfaces of the insulating sheet 40, and the cross-sectional surfaces of the package sheet 60 may be plated (second step 120).

In the third step 130, after the holes 10 are formed, a plurality of feedthrough electrodes 20 are produced by processing the feedthrough sheet 15, so that the plurality of feedthrough electrodes 20 are spaced apart from each other.

Specifically, in the third step 130, the feedthrough sheet 15 is cut into the plurality of feedthrough electrodes 20 spaced apart from each other by a processing method including a computerized numerical control (CNC) machine and a laser, such that the plurality of feedthrough electrodes 20 close the holes 10. In addition, portions of the bottom surfaces of the feedthrough electrodes 20 are exposed downwardly through the holes 10.

In the third step 130, the plurality of feedthrough electrodes 20 are closely adjoined to the top portion of the insulating sheet 40 while closing the open areas in the top portions of the holes 10, respectively. The feedthrough electrodes 20 may be processed into a variety of shapes, including a circular shape and a polygonal shape, as adjusted by a user.

Accordingly, unlike a related-art manual process of inserting metal pins into an insulating sheet to form feedthrough electrodes, the feedthrough fabrication method 100 forms the feedthrough electrodes 20 by an automated process in which the feedthrough sheet 15, the insulating sheet 40, and the package sheet 60 are processed after being diffusion-bonded. Accordingly, the process can be performed rapidly and at low cost, which is advantageous.

In addition, in a related-art case in which a diffusion bonding process is undertaken in a high-temperature, high-pressure, and high-vacuum environment, with the metal pins being inserted into the through-holes in the insulating sheet, pressure may be concentrated to boundaries between the precisely-machined metal pins and the through-holes of the insulating sheet, thereby increasing the possibility of fracture when high pressure is applied thereto. In contrast, in the feedthrough fabrication method 100, the feedthrough sheet 15, the insulating sheet 40, and the package sheet 60, in the shape of sheets or films, are subjected to the diffusion bonding process, thereby advantageously reducing the possibility of fracture to be significantly low.

When a feedthrough structure is produced due to the formation of the plurality of feedthrough electrodes 20, the feedthrough structure is processed for use in various types of encapsulated electronic devices. In the fourth step 140, the insulating sheet 40 is processed so that portions of the top portion of the package sheet 60 are exposed externally.

Specifically, in the fourth step 140, the top portions of the package sheet 60, located on peripheral and inner portions of the feedthrough structure, are externally exposed, so that packages are processed in a shape required for encapsulated electronic devices to which the packages are to be coupled.

In the fifth step 150, portions of the insulating sheet 40, located in inner portions of the feedthrough structure, are processed, so that portions of the package sheet 60 are exposed. The exposed package sheet 60 is cut, thereby dividing the feedthrough structure into individual feedthroughs necessary for encapsulated electronic devices.

Specifically, in the fifth step 150, the feedthrough structure may be fabricated in the shape of a feedthrough array having a large area. In this case, in a position in which portions of the top portion of the package sheet 60, located in peripheral portions of the feedthrough array, are exposed externally, portions of the insulating sheet 40, located inside of the peripheral portions of the feedthrough array, are processed to expose and cut portions of the top surface of the package sheet 60, so that portions of the feedthrough array are separated. The separated portions of the feedthrough array may be used as individual feedthroughs having a shape suitable to encapsulated electronic devices.

In the fifth step 150, peripheral portions of the separated feedthroughs are stair-shaped, with portions of top surfaces of the insulating sheet 40 and the package sheet 60, bonded to the feedthrough electrodes 20, being exposed upwardly.

Since individual feedthroughs are required to have a variety of shapes suitable to encapsulated electronic devices, the individual feedthroughs may be processed in a variety of shapes, such as a circular shape or a polygonal shape, by cutting the insulating sheet 40 and the package sheet 60. The number and arrangement of the feedthrough electrodes 20 required for encapsulated electronic devices may be variously changed, depending on positions in which the holes 10 are processed and the processing of the feedthrough electrodes 20 closing the holes 10.

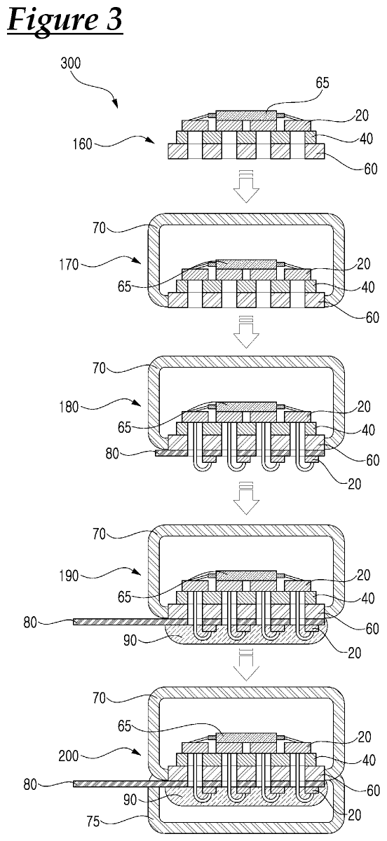

FIG. 3 illustrates process diagrams of a method of fabricating an encapsulated electronic device according to an embodiment of the present disclosure.

An encapsulated electronic device fabrication method 300 is a method of fabricating an encapsulated electronic device by packaging a feedthrough fabricated by the feedthrough fabrication method 100 illustrated in FIG. 1, and includes first to fifth steps 160, 170, 180, 190, and 200.

In the first step 160, the feedthrough electrodes 20 formed on the top portion of the feedthrough, fabricated by the feedthrough fabrication method 100, are connected to a circuit 65.

Specifically, in the first step 160, the top surface of a portion or entirety of the feedthrough electrodes 20 is closely bonded to the bottom surface of the circuit 65, and the feedthrough electrodes 20 are connected to the circuit 65 via wires.

After the first step 160, in the second step 170, a package 70 enclosing the circuit 65, the feedthrough electrodes 20, the insulating sheet 40, and the package sheet 60 is provided.

Specifically, in the second step 170, the package 70 may be made of a titanium material. The package 70 may be bonded to the cut surfaces of the package sheet 60 by a welding method using a laser while enclosing the circuit 65, the feedthrough electrodes 20, the insulating sheet 40, and the package sheet 60.

In the second step 170, in a position in which the package 70 encloses portions of the feedthrough, portions of the bottom surfaces of the feedthrough electrodes 20 are exposed downwardly from the feedthrough through the holes 10.

After the second step 170, in the third step 180, outer electrodes are closely bonded to the bottom surface of the package sheet 60, and are connected to the feedthrough electrodes 20.

Specifically, in the second step 170, the outer electrodes 80 are closely adjoined to the bottom surface of the package sheet 60. The feedthrough electrodes 20 enclosed with the package 70 may be electrically connected to the bottom surfaces of the outer electrodes 80 one bonding method selected from among, but not limited to, wire bonding, welding, soldering, flip chip bonding, and direct bonding using an anisotropic conductive film (ACF) layer. In the case of soldering, a conductive epoxy material or an AuSn material may be used. More specifically, openings may be formed in the outer electrodes 80 to be connected to the holes 10, and the feedthrough electrodes 20 may be connected to the outer electrodes 80 through the openings, respectively, by one method selected from among, but not limited to, wire bonding, welding, and soldering.

In the third step 180, each of the feedthrough electrodes 20 is connected to one end of each of metal wires or metal rods inserted into the holes 10, while the other ends of the metal wires or metal rods extend through the holes 10 to be exposed downwardly and to be coupled to the outer electrodes 80 by soldering or welding, respectively.

After the third step 180, in the fourth step 190, the package sheet 60, coupled to the feedthrough electrodes 20 and the feedthrough electrodes 20, is enclosed with a cover 90 made of a polymer, such as epoxy.

Specifically, in the fourth step 190, the cover 90 is applied to the lower portion of the feedthrough to enclose the bottom surfaces of the outer electrodes 80 corresponding to the lower portion of the feedthrough and the feedthrough electrodes 20 coupled to the outer electrodes 80. In this manner, the cover 90 encapsulates the holes 10, thereby protecting portions of the feedthrough electrodes 20 bonded to the outer electrodes 80.

After the fourth step 190, in the fifth step 200, the cover 90 is encapsulated with a package cap 75.

Specifically, in the fifth step 200, the package cap 75 is made of a metal material, such as titanium, or a titanium alloy. The package cap 75 encloses the cover 90, and is coupled to the package 70 by laser welding to encapsulate the lower portion of the feedthrough, in which the cover 90 is exposed externally, except for outwardly-extending portions of the outer electrodes 80.

Accordingly, the encapsulated electronic device fabrication method 300 is advantageous in that the feedthrough electrodes 20 can be rapidly and accurately packaged by automated diffusion-bonding, etching, cutting, and bonding processes, and in that the position and shape of the feedthrough electrodes 20 can be easily modified.

In addition, since the diffusion bonding is performed when the feedthrough electrodes 20 are in the shape of a film or sheet, the possibility of fracture can be lowered, and high mechanical strength can be obtained. An encapsulated electronic device may be used as a neural electrode of a retina implant (or an artificial eye) to stimulate the optic nerve.

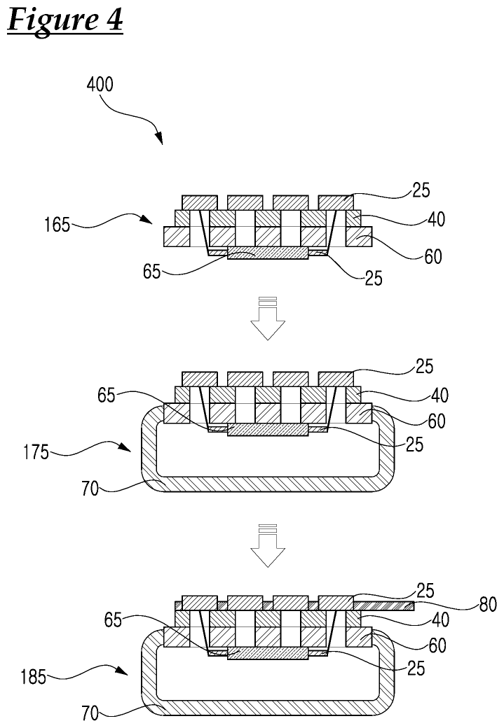

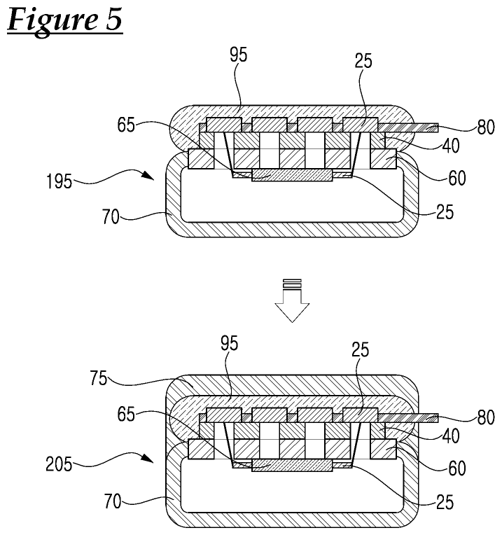

FIGS. 4 and 5 are process diagrams illustrating a method of fabricating an encapsulated electronic device according to another embodiment of the present disclosure.

In an encapsulated electronic device fabrication method 400 according to the present embodiment, the feedthrough is substantially the same as the feedthrough used in the encapsulated electronic device fabrication method 300 illustrated in FIG. 3, except for the fabrication method, the feedthrough electrodes 25, and the circuit 65. The same reference numerals and terms will be used to designate the same components, and repeated descriptions thereof will be omitted.

As illustrated in FIGS. 4 and 5, the encapsulated electronic device fabrication method 400 includes first to fifth steps 165, 175, 185, 195, and 205.

In the first step 165, the circuit 65 is closely adjoined to the bottom surface of the package sheet 60 of the feedthrough fabricated by the feedthrough fabrication method 100 illustrated in FIG. 1 and is connected to feedthrough electrodes 25.

Specifically, the circuit 65 is closely adjoined to a portion or entirety of the bottom surface of the package sheet 60, while portions of the feedthrough electrodes 25 extend through the holes 10 to be coupled to the circuit 65 by wire bonding or by soldering using rods connected to thereto.

After the first step 165, in the second step 175, the package 70 encloses the circuit 65 and the package sheet 60.

Specifically, in the second step 175, the package 70 is coupled to the side surfaces of the package sheet 60 (and the circuit 65) by laser welding to encapsulate the bottom surface of the package sheet 60 and the circuit 65.

After the second step 175, in the third step 185, the feedthrough electrodes 25 disposed on the upper portion of the feedthrough are coupled to the outer electrodes 80.

Specifically, in the third step 185, the feedthrough electrodes 25 are coupled to the outer electrodes 80, respectively, by one bonding method selected from among, but not limited to, wire bonding, welding, soldering, flip chip bonding, and direct bonding using an ACF layer. The soldering may be performed using a conductive epoxy material or an AuSn material may be used. The feedthrough electrodes 25 may be fabricated by one method selected from among, but not limited to, wire bonding, welding, and soldering, in consideration of biocompatibility, since the feedthrough electrodes 25 are disposed outside of the package 70.

After the third step 185, in the fourth step 195, a cover 95 is applied to the feedthrough electrodes 25 and the outer electrodes 80, disposed on the upper portion of the feedthrough.

Specifically, in the fourth step 195, the cover 95 may be made of a polymer material including epoxy or a natural material. The cover 95 may be applied to enclose the feedthrough electrodes 25 and the outer electrodes 80 on the upper portion of the feedthrough to protect the feedthrough electrodes 25 and bonds of the outer electrodes 80.

After the fourth step 195, in the fifth step 205, the cover 95, the feedthrough electrodes 25, and portions of the outer electrodes 80 are enclosed and protected using a package cap 75.

Specifically, in the fifth step 205, the package cap 75 is made of a titanium material. The package cap 75 is in the shape of a cap closely adjoined to the cover 95, and is coupled to the peripheral portions of the package 70 by laser welding to encapsulate the upper portion of the feedthrough, except for externally-extending portions of the outer electrodes 80.

Although the foregoing exemplary embodiments of the present invention have been described with reference to the accompanying drawings, the embodiments described in the specification and the configurations illustrated in the drawings are merely best modes of the present invention, rather than representing all aspects of the scope of the present invention. It should be understood that a variety of equivalents and alternative embodiments could be made at a point in time at which the present application was filed. Accordingly, the foregoing embodiments shall be interpreted as being illustrative, while not being limitative, in all aspects. It should be understood that the scope of the present invention shall be defined by the appended Claims rather than by the foregoing embodiments, and that all of modifications and alterations derived from the definition of the Claims and their equivalents fall within the scope of the present disclosure.

Although the exemplary embodiments of the present invention have been described for illustrative purposes, those skilled in the art will appreciate that various modifications, additions and substitutions are possible, without departing from the scope and spirit of the present invention as disclosed in the accompanying claims.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “e.g.,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

What is claimed is:

1. A feedthrough fabrication method comprising:
stacking a feedthrough sheet, an insulating sheet, and a package sheet sequentially in a vertically downward direction, and diffusion-bonding the feedthrough sheet, the insulating sheet, and the package sheet;
forming holes to penetrate through the package sheet and the insulating sheet; and
forming a plurality of feedthrough electrodes by processing the feedthrough sheet, such that the plurality of feedthrough electrodes close the holes, respectively, and are spaced apart from each other.

2. The feedthrough fabrication method according to claim 1, further comprising cutting the insulating sheet and the package sheet in a shape required for an encapsulated electronic device.

3. The feedthrough fabrication method according to claim 2, wherein, in the cutting the insulating sheet and the package sheet, the insulating sheet and the package sheet are cut by processing portions of the insulating sheet, located in peripheral portions of the shape required for the encapsulated electronic device, so that portions of the package sheet are exposed, and cutting the package sheet along the exposed portions thereof.

4. The feedthrough fabrication method according to claim 1, wherein, in the forming the holes, the holes are formed by etching the package sheet and the insulating sheet such that a bottom surface of the feedthrough sheet is exposed downwardly.

5. The feedthrough fabrication method according to claim 1, wherein the forming the plurality of feedthrough electrodes comprises closing the holes with the feedthrough electrodes, respectively, and processing and removing portions of the feedthrough sheet using a laser or a computerized numerical control machine to be separated from each other.

6. A method of fabricating an encapsulated electronic device using a feedthrough fabricated by a feedthrough fabrication method including stacking a feedthrough sheet, an insulating sheet, and a package sheet sequentially in a vertically downward direction, and diffusion-bonding the feedthrough sheet, the insulating sheet, and the package sheet, forming holes to penetrate through the package sheet and the insulating sheet, and forming a plurality of feedthrough electrodes by processing the feedthrough sheet, such that the plurality of feedthrough electrodes close the holes, respectively, and are spaced apart from each other, the method comprising:
connecting the feedthrough electrodes to a circuit;
forming a package connected to a peripheral portion of the package sheet to enclose the circuit; and
connecting the feedthrough electrodes to outer electrodes through the holes, the outer electrodes being exposed externally from the package and connected to the package sheet, and encapsulating the outer electrodes and the feedthrough electrodes.

7. The method according to claim 6, wherein, in the connecting the feedthrough electrodes to the circuit, the feedthrough electrodes are connected to the circuit by connecting the circuit to the feedthrough electrodes through the holes, with the insulating sheet and the package sheet being situated between the feedthrough electrodes and the circuit, or disposing the circuit to be closely adjoined to the feedthrough electrodes.

8. The method according to claim 6, wherein the forming the package comprises bonding the package to a cut side surface of the package sheet by laser welding while enclosing the circuit and the insulating sheet, the package comprising titanium.

9. The method according to claim 6, wherein the encapsulating the outer electrodes and the feedthrough electrodes comprises:
forming openings in the outer electrodes to be connected the holes; and
connecting the feedthrough electrodes to the outer electrodes through the openings, respectively, by one selected from among wire bonding, welding, and soldering.

10. The method according to claim 9, wherein the encapsulating the outer electrodes and the feedthrough electrodes comprises:
encapsulating connecting portions of the outer electrodes and the feedthrough electrodes by applying a cover comprising epoxy to the connecting portions;
enclosing the applied cover with a package cap; and
welding the package cap to the package.
